(19) United States
(12) Patent Application Publication
(10) Pub. No.: US 2025/0071951 A1
(43) Pub. Date: Feb. 27, 2025

(54) AIR CONDITIONING UNIT FOR DATA ROOM AND CONTROL METHOD THEREOF

(71) Applicant: Hebei Qinhuai Data Co., Limited., Zhangjiakou City (CN)

(72) Inventor: Binghua ZHANG, Zhangjiakou City (CN)

(21) Appl. No.: 18/810,212

(22) Filed: Aug. 20, 2024

(30) Foreign Application Priority Data
Aug. 23, 2023 (CN) 202311068486.8

(51) Int. Cl. H05K 7/20

(52) U.S. Cl. CPC H05K 7/20827; H05K 7/20327; H05K 7/20354

(57) ABSTRACT

The present disclosure discloses an air conditioning unit for a data room and a control method thereof. The air conditioning unit for the data room includes a plurality of outdoor finned heat exchangers, a plurality of corresponding outdoor cooling heat exchanger fans, a plurality of indoor cooling heat exchanger fans, an indoor finned heat exchanger, an indoor humidifier, a full-variable-speed two-stage compression oil-free centrifugal compressor, a refrigerant circulating pump, an electronic expansion valve, an electromagnetic valve, an indoor air supply duct, and a refrigerant circulation pipeline. The unit performs natural cooling by means of the plurality of outdoor finned heat exchangers in combination with the corresponding fans, and the compressor is started to perform mechanical refrigeration. Quantity of refrigerants entering the indoor finned heat exchanger is adjusted by regulating opening degree of the electronic expansion valve and the electromagnetic valve, and supply air humidity is regulated through the indoor humidifier.

### CROSS REFERENCE TO RELATED APPLICATION

This application claims priority to Chinese Patent Application No. 202311068486.8, titled “AIR CONDITIONING UNIT FOR DATA ROOM AND CONTROL METHOD THEREOF” and filed to the China National Intellectual Property Administration on Aug. 23, 2023, the entire contents of which are incorporated herein by reference.

### TECHNICAL FIELD

The present disclosure relates to the field of data center air conditioning technology, and more particularly, to an air conditioning unit for a data room and a control method thereof.

### BACKGROUND

With the development of scale and integration of data centers, power density and heat density of server devices are increasing day by day, which brings two problems as below. In one aspect, consumption of electricity in computer rooms has increased significantly. In another aspect, cooling issues of servers have become increasingly severe because a large amount of energy is consumed. Furthermore, due to unreasonable cooling regulation, device shutdown may occur due to overheating.

The traditional data rooms use mechanical refrigeration, and electric energy consumed by the refrigeration accounts for more than 35% of the energy consumption of the data rooms, and the refrigeration effects need to be improved, which brings certain difficulties to daily management of the data centers. At present, indirect evaporative cooling air conditioning units on the market need to consume a lot of energy (electric energy, water resources), and may use a lot of cooling water in regulating processes. An air conditioning unit for a data room is designed, which not only has better refrigeration effects, but also can meet requirements of uniform temperature and humidity of cold air fed into the data room during all the regulating processes by arranging a humidifier in an air outlet channel through accurate regulation. Use of natural cold sources can be maximized, and there is no need to use cooling water, which has better economic and social benefits especially for water-deficient areas. Furthermore, energy consumption of the air conditioning unit for the data room can also be reduced, which is a technical problem that urgently needs to be solved at present.

### SUMMARY

To solve problems of lower utilization of natural cold sources, unreasonable adjustment and control of data room temperature, mismatch between traditional evaporative cooling unit spray cooling and load of a cooling side, higher water consumption, unreasonable investment time of mechanical refrigeration, longer running time and higher energy consumption, an air conditioning unit for a data room according to the present disclosure completes accurate air conditioning of the data center room during year-round operation. The air conditioning unit uses a two-stage compression oil-free centrifugal compressor and a refrigerant circulating pump subjected to full-variable-speed control, and there is no need to use cooling water. Temperature and humidity of cold air fed into a channel of the data room are processed to ensure that supply air temperature meets requirements of the data room. In this way, a problem of lower utilization rate of natural cold sources for air conditioning of the data center is solved, there is no need to additionally provide a dehumidifier unit in the data room, requirements for normal operation of the data room can be met, and air-conditioning energy consumption can be reduced. Embodiments of the present disclosure provide an air conditioning unit for a data room and a control method thereof. The technical solutions are described as follows.

In one aspect, there is provided an air conditioning unit for a data room, comprising: a plurality of outdoor finned heat exchangers, a plurality of corresponding outdoor cooling heat exchanger fans, a plurality of indoor cooling heat exchanger fans, an indoor finned heat exchanger, an indoor humidifier, a two-stage compression oil-free centrifugal compressor, a refrigerant circulating pump, an electronic expansion valve, an electromagnetic valve, an indoor air supply duct, and a refrigerant circulation connection pipeline.

The plurality of outdoor finned heat exchangers are arranged in one-to-one correspondence with the plurality of corresponding outdoor cooling heat exchanger fans. A given one of the plurality of indoor cooling heat exchanger fans is configured to drive return air from the data room to enter the indoor air supply duct after the return air is subjected to heat exchange through the given indoor finned heat exchanger. The two-stage compression oil-free centrifugal compressor, the refrigerant circulating pump, the electronic expansion valve, and the electromagnetic valve are configured to regulate a refrigerant entering the given indoor finned heat exchanger, such that a cycle of heat exchange between the refrigerant and the plurality of outdoor finned heat exchangers is completed. The indoor humidifier is configured to humidify air entering the indoor air supply duct.

Further, the air conditioning unit for the data room also includes a check valve arranged between the indoor finned heat exchanger and the two-stage compression oil-free centrifugal compressor to achieve a one-way flow of a condensate liquid to the two-stage compression oil-free centrifugal compressor.

Further, the refrigerant circulation connection pipeline includes: a pipeline connecting between the indoor finned heat exchanger and the two-stage compression oil-free centrifugal compressor, a pipeline connecting between the two-stage compression oil-free centrifugal compressor and the plurality of outdoor finned heat exchangers, a refrigerant liquid main pipeline connecting between the plurality of outdoor finned heat exchangers and the refrigerant circulating pump, a pipeline connecting between the refrigerant circulating pump and the electronic expansion valve and the electromagnetic valve, and a pipeline connecting between the electronic expansion valve, the electromagnetic valve, and the indoor finned heat exchanger.

Further, the refrigerant circulating pump is a full-variable-speed refrigerant circulating pump configured to carry out variable-speed pressurization on a refrigerant liquid condensed by the plurality of outdoor finned heat exchangers.

Further, the two electronic expansion valves are adjustable in opening degree, and on-off of the electromagnetic valve is controllable to regulate a flow rate of the refrigerant entering the indoor finned heat exchanger.

In another aspect, there is provided a control method for the air conditioning unit for the data room, which includes:
in a first mode, regulating air volume of the plurality of outdoor cooling heat exchanger fans, cooling a refrigerant gas flowing through the outdoor finned heat exchanger by means of an outdoor natural cold source to transfer heat to outside air, such that the refrigerant is liquified; adjusting rotational speed of the refrigerant circulating pump to pressurize the liquefied refrigerant; adjusting an opening degree of the electronic expansion valve and turning on the electromagnetic valve, such that the liquefied refrigerant enters the indoor finned heat exchanger after reaching a required low pressure, to exchange heat with hot air from the data room; and regulating air volume of the indoor cooling heat exchanger fan and spray volume of the indoor humidifier to feed treated air into the data room;
in a second mode, further reducing the air volume of the plurality of outdoor cooling heat exchanger fans and reducing number of the outdoor finned heat exchangers, other steps being the same as the first mode;
in a third mode, further reducing the air volume of the plurality of outdoor cooling heat exchanger fans and reducing the number of the outdoor finned heat exchangers, other steps being the same as the first mode;
in a fourth mode, turning off all the plurality of outdoor cooling heat exchanger fans, turning off all the plurality of outdoor finned heat exchangers, regulating the air volume of the indoor cooling heat exchanger fan and the spray volume of the indoor humidifier to fed the treated air into the data room;
in a fifth mode, starting the two-stage compression oil-free centrifugal compressor, turning on all the plurality of outdoor cooling heat exchanger fans, and heating the refrigerant by means of mechanical compression, other steps being the same as the first mode;
in a sixth mode, adjusting the opening degree of the electronic expansion valve and turning off the electromagnetic valve, such that amount of the refrigerant entering the indoor finned heat exchanger is reduced, other steps being the same as the first mode; and
in a seventh mode, regulating the spray amount of the indoor humidifier and increasing moisture content in the air, other steps being the same as the first mode.

Further, the first mode is suitable for a case where outdoor temperature is lower and heat load of the data room is greater. The second mode is suitable for a case where the outdoor temperature and the heat load of the data room are further reduced. The third mode is suitable for a case where the outdoor temperature and the heat load of the data room are still further reduced. The fourth mode is suitable for a case where the outdoor temperature is extremely low and the heat load of the data room is smaller. The fifth mode is suitable for a case where the outdoor temperature rises and the heat load of the data room is greater. The sixth mode is suitable for a case where the data room has higher dehumidification demands. The seventh mode is suitable for a case where the data room needs to increase dehumidification capacity.

Further, the plurality of outdoor cooling heat exchanger fans, the two-stage compression oil-free centrifugal compressor, and the refrigerant circulating pump are under full-variable-speed control, and variable-frequency speed regulation operation is implemented according to their respective modes and load requirements of the data room, to achieve accurate control and improve energy efficiency.

Further, operation modes of devices are automatically switched on a basis of hot air parameters from the data room and outdoor environmental parameters in combination with a pre-set control logic.

Further, the hot air parameters include temperature and humidity. The environmental parameters include temperature and humidity. The control logic is set in advance according to requirements for air supply parameters of the data room, such as a temperature range and a humidity range.

The technical solutions provided the embodiments of the present disclosure achieve the following beneficial effects.

The present disclosure provides an air conditioning unit for a data room and a control method thereof, which can achieve accurate temperature adjustment of a data center room. During whole year operation, through accurate adjustment and control, the temperature adjustment of the data center room can be carried out by means of seasonal and diurnal temperature variations and natural cold sources, to reduce time and load of mechanical refrigeration operation. By using the two-stage compression oil-free centrifugal compressor technology with higher refrigeration efficiency to meet fine regulation of mechanical refrigeration, there is no need to use cooling water. The temperature and the humidity of the cold air fed into a channel of the data room are processed to meet strict requirements for the temperature and the humidity of supply air in the data room. In this way, energy consumption of air conditioning for the data center room is reduced, and there is no need of consumption of the water sources.

### BRIEF DESCRIPTION OF THE DRAWINGS

To describe the technical solutions in the embodiments of the present disclosure more clearly, the following will briefly introduce the accompanying drawings required for describing the embodiments. Apparently, the accompanying drawings in the following description show merely some embodiments of the present disclosure, and a person of ordinary skill in the art may still derive other drawings from these accompanying drawings without creative efforts.

FIG. 1 is a schematic diagram of an air conditioning unit for a data room according to Embodiment 1 of the present disclosure;

FIG. 2 is a schematic diagram of a first operating mode in a control method of the air conditioning unit for the data room according to Embodiment 2 of the present disclosure;

FIG. 3 is a schematic diagram of a second operating mode in the control method of the air conditioning unit for the data room according to the Embodiment 2 of the present disclosure;

FIG. 4 is a schematic diagram of a third operating mode in the control method of the air conditioning unit for the data room according to the Embodiment 2 of the present disclosure;

FIG. 5 is a schematic diagram of a fourth operating mode in the control method of the air conditioning unit for the data room according to the Embodiment 2 of the present disclosure;

FIG. 6 is a schematic diagram of a fifth operating mode in the control method of the air conditioning unit for the data room according to the Embodiment 2 of the present disclosure;

FIG. 7 is a schematic diagram of a sixth operating mode in the control method of the air conditioning unit for the data room according to the Embodiment 2 of the present disclosure; and

FIG. 8 is a schematic diagram of a seventh operating mode in the control method of the air conditioning unit for the data room according to the Embodiment 2 of the present disclosure.

In the figures, 1 represents a refrigerant liquid main pipeline, 2 represents a refrigerant circulating pump, both 3a and 3b represent electronic expansion valves, 4 represents an electromagnetic valve, 5 represents a refrigerant circulating pump liquid outlet pipeline, 6, 7, 8, 9, 10, 11 and 12 all represent refrigerant throttling distribution pipelines, 13 represents an indoor finned heat exchanger, 14 represents an indoor finned heat exchanger gas return pipeline, 15 represents a connection pipeline, 16 represents a gas suction pipeline, 17a, 17b, 17c, and 17d all represent indoor cooling heat exchanger fans, 18 represents an indoor humidifier, 19 represents an indoor air supply channel, 20 represents a two-stage compression oil-free centrifugal compressor, 21 represents a gas exhaust pipeline, 22 represents a check valve, 24 represents an air inlet manifold, 28, 38, 45, and 52 represent outdoor cooling heat exchanger fans, 26/30, 33/36, 40/43 and 47/50 represent outdoor finned heat exchangers, and 25/29, 32/37, 39/44 and 46/51 represent outdoor finned heat exchanger gas inlet pipelines.

### DETAILED DESCRIPTION

To make the objects, technical solutions and advantages of the present disclosure clearer, the implementation of the present disclosure is further described as below in details with reference to the accompanying drawings.

### Embodiment 1

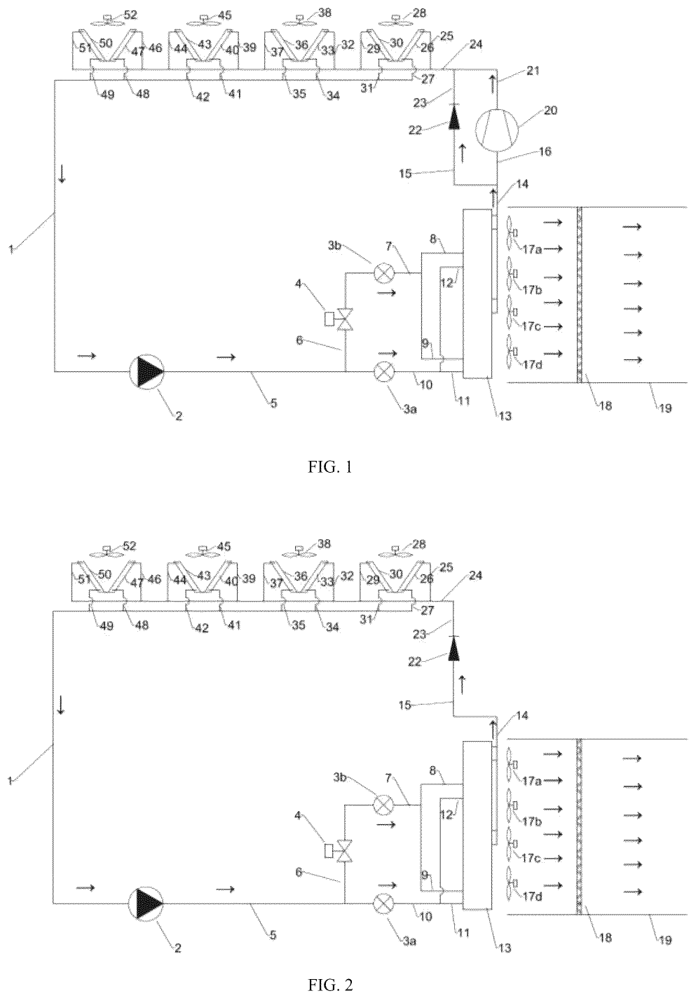

The present disclosure provides an air conditioning unit for a data room, as shown in FIG. 1, including a two-stage compression oil-free centrifugal compressor 20, outdoor heat exchanger fans 28, 38, 45, and 51; outdoor heat exchangers 26/30, 33/36, 40/43, and 47/50; outdoor heat exchanger gas inlet pipeline 25/29, 32/37, 39/44, and 46/51; outdoor heat exchanger liquid outlet pipelines 27/31, 34/35, 41/42, and 48/49; a refrigerant liquid main pipeline 1; a refrigerant circulating pump 2; a refrigerant circulating pump liquid outlet pipeline 5; electronic expansion valves 3a and 3b; an electromagnetic valve 4; refrigerant throttling distribution pipelines 6, 7, 8, 9, 10, 11, and 12; an indoor finned heat exchanger 13; indoor heat exchanger fans 17a, 17b, 17c, and 17d; an indoor finned heat exchanger gas return pipeline 14; an indoor air supply channel 19, and a humidifier 18. The two-stage compression oil-free centrifugal compressor 20 is a full-variable-speed control two-stage compression oil-free centrifugal compressor, including a gas suction pipeline 16, a gas exhaust pipeline 21, a check valve 22, and connection pipelines 15 and 23.

The plurality of outdoor finned heat exchangers 6/30, 33/36, 40/43, and 47/50 are arranged in one-to-one correspondence with the plurality of corresponding outdoor cooling heat exchanger fans 28, 38, 45, and 52. The indoor cooling heat exchanger fans 17a, 17b, 17c and 17d are configured to drive return air from the data room to enter the indoor air supply duct 19 after the return air is subjected to heat exchange through the indoor finned heat exchanger 13. The two-stage compression oil-free centrifugal compressor 20, the refrigerant circulating pump 2, the electronic expansion valves 3a and 3b, and the electromagnetic valve 4 are configured to regulate a refrigerant entering the indoor finned heat exchanger 13, such that a cycle of heat exchange between the refrigerant and the plurality of outdoor finned heat exchangers is completed. The indoor humidifier 18 is configured to humidify air entering the indoor air supply duct 19.

The air conditioning unit for the data room of the present disclosure also includes a check valve 22, where the check valve 22 is arranged between the indoor finned heat exchanger 13 and the two-stage compression oil-free centrifugal compressor 20 to achieve a one-way flow of a condensate liquid to the two-stage compression oil-free centrifugal compressor 20.

The refrigerant circulation connection pipeline includes: a connection pipeline 15 connecting between the indoor finned heat exchanger 13 and the two-stage compression oil-free centrifugal compressor 20; an air inlet manifold 24 connecting between the two-stage compression oil-free centrifugal compressor 20 and the plurality of outdoor finned heat exchangers; a refrigerant liquid main pipeline 1 connecting between the plurality of outdoor finned heat exchangers and the refrigerant circulating pump 2; a pipeline 5 connecting between the refrigerant circulating pump 2 and the electronic expansion valves 3a and 3b and the electromagnetic valve 4; and pipelines 7, 8, 9, 10, 11 and 12 connecting between the electronic expansion valves 3a and 3b, the electromagnetic valve 4, and the indoor finned heat exchanger 13.

The refrigerant circulating pump 2 is a full-variable-speed refrigerant circulating pump configured to carry out variable-speed pressurization on a refrigerant liquid condensed by the plurality of outdoor finned heat exchangers. The two electronic expansion valves 3a and 3b are adjustable in opening degree, and on-off of the electromagnetic valve 4 is controllable to regulate a flow rate of the refrigerant entering the indoor finned heat exchanger 13.

### Embodiment 2

A control method for the air conditioning unit for the data room of the present disclosure corresponds to different operating modes as follows.

As shown in FIG. 2, in a first operating mode, guided by the indoor air duct and driven by the indoor heat exchanger fan 17a/17b/17c/17d, hot air from the data room flows into the indoor finned heat exchanger 13. After being subjected to heat exchange with a refrigerant evaporated after throttling, the refrigerated air flows out of an indoor heat exchange channel of the indoor finned heat exchanger 13 and then flows through the indoor humidifier. Next, the refrigerated air is fed into the data room through the indoor air supply channel 19 to cool servers therein.

The refrigerant gas evaporated in the indoor finned heat exchanger flows through the connection pipeline 15 via the indoor finned heat exchanger gas return pipeline 14, then flows into the check valve 22, and then flows, through the connection pipeline 23, into a gas exhaust manifold 24. Next, the refrigerant gas flows, through the outdoor finned heat exchanger gas inlet pipelines 25/29, 32/37, 39/44 and 46/51, into the outdoor finned heat exchangers 26/30, 33/36, 40/43, and 47/50. By adjusting the outdoor cooling heat exchanger fans 28, 38, 45 and 52, the refrigerant in the outdoor heat exchanger is cooled, and heat of the refrigerant is discharged into atmosphere. The cooled refrigerant is changed from gas to liquid, and flows, through the outdoor finned heat exchanger liquid outlet pipelines 27/31, 34/35, 41/42 and 48/49 respectively, into the refrigerant liquid main pipeline 1. Next, after being pressurized by the refrigerant circulating pump, the refrigerant is fed into the electronic expansion valve 3a, the electromagnetic valve 4 and the electronic expansion valve 3b for throttling respectively through the refrigerant circulating pump liquid outlet pipeline 5. The throttled refrigerant flows, through the refrigerant throttling distribution pipelines 6, 7, 8, 9, 10, 11 and 12 again, into the indoor finned heat exchanger 13 for evaporation, and then the evaporated refrigerant flows through the gas return pipeline again. In this way, a complete refrigeration cycle is formed.

According to indoor load of the data room, the outdoor heat exchanger fans 28, 38, 45 and 51 and the indoor cooling heat exchanger fans 17a, 17b, 17c and 17d are adjusted respectively to obtain a stable target temperature on an indoor side, thereby reducing power consumption of the outdoor and indoor heat exchanger fans. The target temperature required for the indoor side may be obtained by means of natural cooling, and there is no need to start the compressor to run, thereby saving energy consumption.

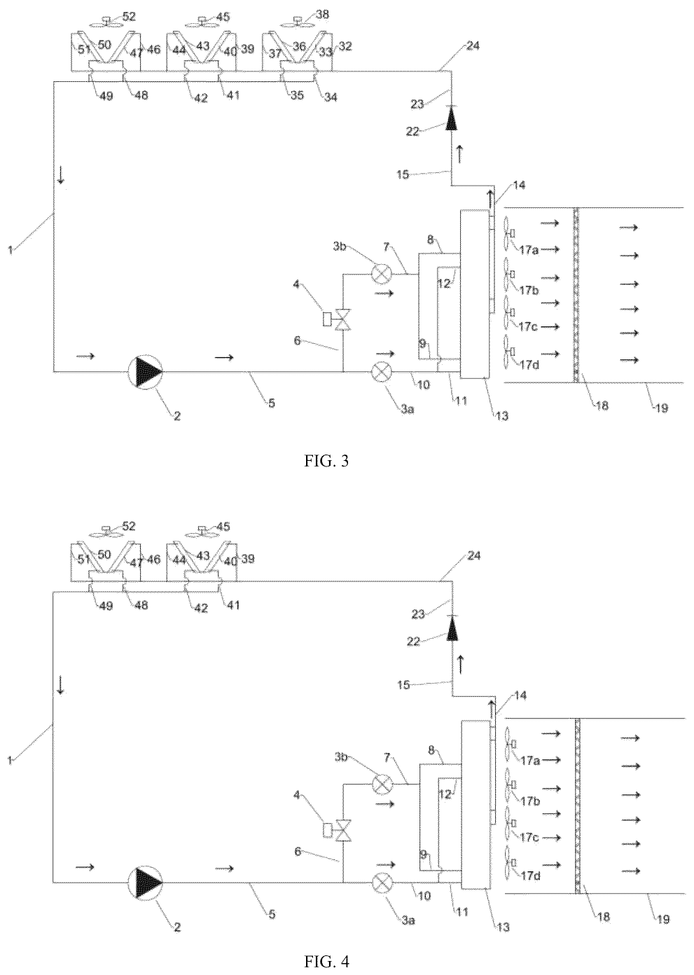

As shown in FIG. 3, in a second operating mode, when outdoor air temperature drops and the indoor load decreases, indoor air supply temperature is lower than a set target temperature if the outdoor fan is adjusted to the minimum load when the unit is in the first operating mode. In this case, the unit enters the second operating mode. Guided by the indoor air duct and driven by the indoor heat exchanger fan 17a/17b/17c/17d, the hot air from the data room flows into the indoor finned heat exchanger 13. After being subjected to heat exchange with the refrigerant evaporated after throttling, the refrigerated air flows out of the indoor heat exchange channel of the indoor finned heat exchanger 13 and then flows through the indoor humidifier. Next, the refrigerated air is fed into the data room through the indoor air supply channel 19 to cool the servers therein.

The refrigerant gas evaporated in the indoor finned heat exchanger flows through the connection pipeline 15 via the indoor finned heat exchanger gas return pipeline 14, then flows into the check valve 22, and then flows, through the connection pipeline 23, into the gas exhaust manifold 24. Next, the refrigerant gas flows, through the outdoor finned heat exchanger gas inlet pipelines 32/37, 39/44 and 46/51, into the outdoor finned heat exchangers 33/36, 40/43, and 47/50. By adjusting the outdoor cooling heat exchanger fans 38, 45 and 52, the refrigerant in the outdoor heat exchanger is cooled, and heat of the refrigerant is discharged into the atmosphere. The cooled refrigerant is changed from gas to liquid, and flows, through the outdoor finned heat exchanger liquid outlet pipelines 34/35, 41/42 and 48/49 respectively, into the refrigerant liquid main pipeline 1. Next, after being pressurized by the refrigerant circulating pump, the refrigerant is fed into the electronic expansion valve 3a, the electromagnetic valve 4 and the electronic expansion valve 3b for throttling respectively through the refrigerant circulating pump liquid outlet pipeline 5. The throttled refrigerant flows, through the refrigerant throttling distribution pipelines 6, 7, 8, 9, 10, 11 and 12 again, into the indoor finned heat exchanger 13 for evaporation, and then the evaporated refrigerant flows through the gas return pipeline again. In this way, a complete refrigeration cycle is formed.

According to the indoor load of the data room, the outdoor heat exchanger fans 38, 45 and 51 and the indoor cooling heat exchanger fans 17a, 17b, 17c and 17d are adjusted respectively to obtain the stable target temperature on the indoor side, thereby reducing the power consumption of the outdoor and indoor heat exchanger fans. The target temperature required for the indoor side may be obtained by means of natural cooling, and there is no need to start the compressor to run, thereby saving the energy consumption.

As shown in FIG. 4, in a third operating mode, when the outdoor air temperature drops and the indoor load decreases, the indoor air supply temperature is lower than the set target temperature if the outdoor fan is adjusted to the minimum load when the unit is in the second operating mode. In this case, the unit enters the third operating mode. Guided by the indoor air duct and driven by the indoor heat exchanger fan 17a/17b/17c/17d, the hot air from the data room flows into the indoor finned heat exchanger 13. After being subjected to heat exchange with the refrigerant evaporated after throttling, the refrigerated air flows out of the indoor heat exchange channel of the indoor finned heat exchanger 13 and then flows through the indoor humidifier. Next, the refrigerated air is fed into the data room through the indoor air supply channel 19 to cool the servers therein.

The refrigerant gas evaporated in the indoor finned heat exchanger flows through the connection pipeline 15 via the indoor finned heat exchanger gas return pipeline 14, then flows into the check valve 22, and then flows, through the connection pipeline 23, into the gas exhaust manifold 24. Next, the refrigerant gas flows, through the outdoor finned heat exchanger gas inlet pipelines 39/44 and 46/51, into the outdoor finned heat exchangers 40/43, and 47/50. By adjusting the outdoor cooling heat exchanger fans 45 and 52, the refrigerant in the outdoor heat exchanger is cooled, and the heat of the refrigerant is discharged into the atmosphere. The cooled refrigerant is changed from gas to liquid, and flows, through the outdoor finned heat exchanger liquid outlet pipelines 41/42 and 48/49 respectively, into the refrigerant liquid main pipeline 1. Next, after being pressurized by the refrigerant circulating pump, the refrigerant is fed into the electronic expansion valve 3a, the electromagnetic valve 4 and the electronic expansion valve 3b for throttling respectively through the refrigerant circulating pump liquid outlet pipeline 5. The throttled refrigerant flows, through the refrigerant throttling distribution pipelines 6, 7, 8, 9, 10, 11 and 12 again, into the indoor finned heat exchanger 13 for evaporation, and then the evaporated refrigerant flows through the gas return pipeline again. In this way, a complete refrigeration cycle is formed.

According to the indoor load of the data room, the outdoor heat exchanger fans 45 and 51 and the indoor cooling heat exchanger fans 17a, 17b, 17c and 17d are adjusted respectively to obtain the stable target temperature on the indoor side, thereby reducing the power consumption of the outdoor and indoor heat exchanger fans. The target temperature required for the indoor side may be obtained by means of natural cooling, and there is no need to start the compressor to run, thereby saving the energy consumption.

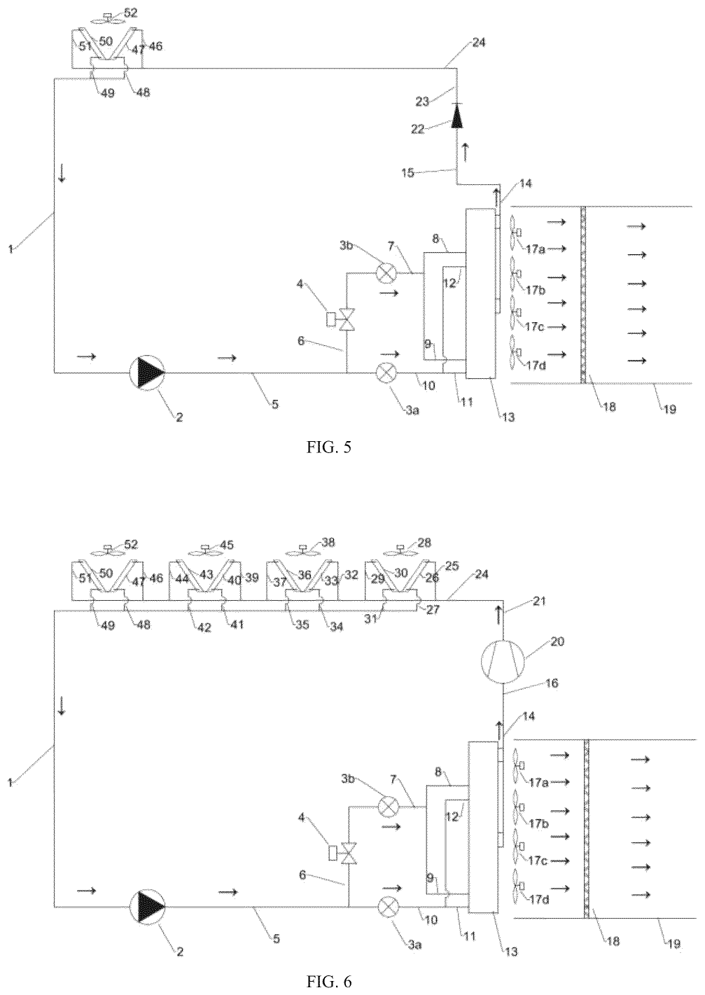

As shown in FIG. 5, in a fourth operating mode, when the outdoor air temperature drops and the indoor load decreases, the indoor air supply temperature is lower than the set target temperature if the outdoor fan is adjusted to the minimum load when the unit is in the third operating mode. In this case, the unit enters the fourth operating mode. Guided by the indoor air duct and driven by the indoor heat exchanger fan 17a/17b/17c/17d, the hot air from the data room flows into the indoor finned heat exchanger 13. After being subjected to heat exchange with the refrigerant evaporated after throttling, the refrigerated air flows out of the indoor heat exchange channel of the indoor finned heat exchanger 13 and then flows through the indoor humidifier. Next, the refrigerated air is fed into the data room through the indoor air supply channel 19 to cool the servers therein.

The refrigerant gas evaporated in the indoor finned heat exchanger flows through the connection pipeline 15 via the indoor finned heat exchanger gas return pipeline 14, then flows into the check valve 22, and then flows, through the connection pipeline 23, into the gas exhaust manifold 24. Next, the refrigerant gas flows, through the outdoor finned heat exchanger gas inlet pipeline 46/51, into the outdoor finned heat exchanger 47/50. By adjusting the outdoor cooling heat exchanger fan 52, the refrigerant in the outdoor heat exchanger is cooled, and the heat of the refrigerant is discharged into the atmosphere. The cooled refrigerant is changed from gas to liquid, and flows, through the outdoor finned heat exchanger liquid outlet pipeline 48/49, into the refrigerant liquid main pipeline 1. Next, after being pressurized by the refrigerant circulating pump, the refrigerant is fed into the electronic expansion valve 3a, the electromagnetic valve 4 and the electronic expansion valve 3b for throttling respectively through the refrigerant circulating pump liquid outlet pipeline 5. The throttled refrigerant flows, through the refrigerant throttling distribution pipelines 6, 7, 8, 9, 10, 11 and 12 again, into the indoor finned heat exchanger 13 for evaporation, and then the evaporated refrigerant flows through the gas return pipeline again. In this way, a complete refrigeration cycle is formed.

According to the indoor load of the data room, the outdoor heat exchanger fan 51 and the indoor cooling heat exchanger fans 17a, 17b, 17c and 17d are adjusted respectively to obtain the stable target temperature on the indoor side, thereby reducing the power consumption of the outdoor and indoor heat exchanger fans. The target temperature required for the indoor side may be obtained by means of natural cooling, and there is no need to start the compressor to run, thereby saving the energy consumption.

As shown in FIG. 6, in a fifth operating mode, when the outdoor air temperature rises, the target temperature after heat exchange cannot be met if the unit is in the first operating mode. In this case, guided by the indoor air duct and driven by the indoor heat exchanger fan 17a/17b/17c/17d, the hot air from the data room flows into the indoor finned heat exchanger 13. After being subjected to the heat exchange with the refrigerant evaporated after throttling, the refrigerated air flows out of the indoor heat exchange channel of the indoor finned heat exchanger 13 and then flows through the indoor humidifier. Next, the refrigerated air is fed into the data room through the indoor air supply channel 19 to cool the servers therein.

The evaporated refrigerant gas in the indoor finned heat exchanger flows, through the gas suction pipeline 16 via the indoor finned heat exchanger gas return pipeline 14, into the two-stage compression oil-free centrifugal compressor 20 for compression, and then flows into the gas exhaust manifold 24 through the gas exhaust pipeline 21. Next, the refrigerant gas flows, through the outdoor finned heat exchanger gas inlet pipelines 25/29, 32/37, 39/44 and 46/51 respectively, into the outdoor finned heat exchangers 26/30, 33/36, 40/43, and 47/50. By adjusting the outdoor cooling heat exchanger fans 28, 38, 45 and 52, the refrigerant in the outdoor heat exchanger is cooled, and the heat of the refrigerant is discharged into the atmosphere. The cooled refrigerant is changed from gas to liquid, and flows, through the outdoor finned heat exchanger liquid outlet pipelines 27/31, 34/35, 41/42 and 48/49, into the refrigerant liquid main pipeline 1. Next, after being pressurized by the refrigerant circulating pump 2, the refrigerant is fed into the electronic expansion valve 3a, the electromagnetic valve 4 and the electronic expansion valve 3b for throttling respectively through the refrigerant circulating pump liquid outlet pipeline 5. The throttled refrigerant flows, through the refrigerant throttling distribution pipelines 6, 7, 8, 9, 10, 11 and 12 again, into the indoor finned heat exchanger 13 for evaporation, and then the evaporated refrigerant flows through the gas return pipeline again. In this way, a complete refrigeration cycle is formed.

According to indoor load of the data room, the outdoor heat exchanger fans 28, 38, 45 and 51 and the indoor cooling heat exchanger fans 17a, 17b, 17c and 17d are adjusted respectively to obtain a stable target temperature on an indoor side, thereby reducing power consumption of the outdoor and indoor heat exchanger fans. The two-stage compression oil-free centrifugal compressor carries out full-variable-speed control according to load requirements of the data room, which can save energy consumption.

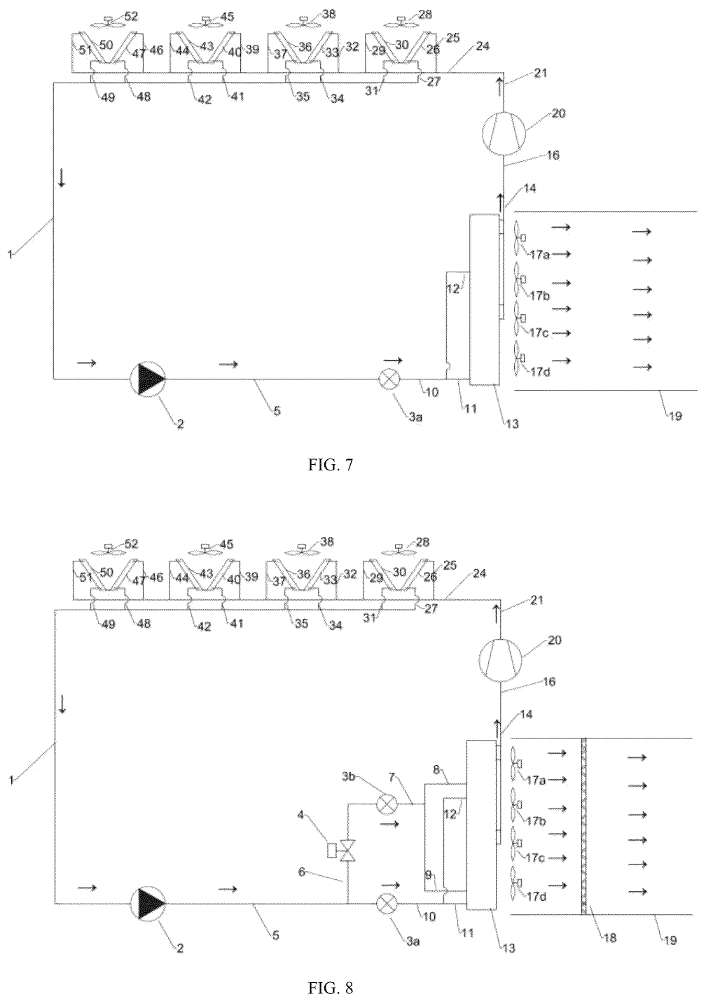

As shown in FIG. 7, in a sixth operating mode, when target humidity of the data room after heat exchange cannot be met if the unit is in the first operating mode, guided by the indoor air duct and driven by the indoor heat exchanger fan 17a/17b/17c/17d, the hot air from the data room flows into the indoor finned heat exchanger 13. After being subjected to the heat exchange with the refrigerant evaporated after throttling, the refrigerated air flows out of the indoor heat exchange channel of the indoor finned heat exchanger 13 and then flows through the indoor humidifier. Next, the refrigerated air is fed into the data room through the indoor air supply channel 19 to cool the servers therein.

The evaporated refrigerant gas in the indoor finned heat exchanger flows, through the gas suction pipeline 16 via the indoor finned heat exchanger gas return pipeline 14, into the two-stage compression oil-free centrifugal compressor 20 for compression, and then flows into the gas exhaust manifold 24 through the gas exhaust pipeline 21. Next, the refrigerant gas flows, through the outdoor finned heat exchanger gas inlet pipelines 25/29, 32/37, 39/44 and 46/51 respectively, into the outdoor finned heat exchangers 26/30, 33/36, 40/43, and 47/50. By adjusting the outdoor cooling heat exchanger fans 28, 38, 45 and 52, the refrigerant in the outdoor heat exchanger is cooled, and the heat of the refrigerant is discharged into the atmosphere. The cooled refrigerant is changed from gas to liquid, and flows, through the outdoor finned heat exchanger liquid outlet pipelines 27/31, 34/35, 41/42 and 48/49, into the refrigerant liquid main pipeline 1. Next, after being pressurized by the refrigerant circulating pump 2, the refrigerant is fed into the electronic expansion valve 3a for throttling through the refrigerant circulating pump liquid outlet pipeline 5, and both the electromagnetic valve 4 and the electronic expansion valve 3b are turned off. The throttled refrigerant flows, through the refrigerant throttling distribution pipelines 10, 11 and 12 again, into the indoor finned heat exchanger 13 for evaporation, and then the evaporated refrigerant flows through the gas return pipeline again. In this way, a complete refrigeration cycle is formed.

According to the indoor load of the data room, the outdoor heat exchanger fans 28, 38, 45 and 51 and the indoor cooling heat exchanger fans 17a, 17b, 17c and 17d are adjusted respectively to obtain a stable target temperature on an indoor side, thereby reducing power consumption of the outdoor and indoor heat exchanger fans. The two-stage compression oil-free centrifugal compressor carries out full-variable-speed control according to load requirements of the data room, which can save energy consumption.

As shown in FIG. 8, in a seventh operating mode, when the target humidity of the data room after heat exchange cannot be met if the unit is in the first operating mode, guided by the indoor air duct and driven by the indoor heat exchanger fan 17a/17b/17c/17d, the hot air from the data room flows into the indoor finned heat exchanger 13. After being subjected to the heat exchange with the refrigerant evaporated after throttling, the refrigerated air flows out of the indoor heat exchange channel of the indoor finned heat exchanger 13 and then flows through the indoor humidifier. Next, the refrigerated air is fed into the data room through the indoor air supply channel 19 to cool the servers therein.

The evaporated refrigerant gas in the indoor finned heat exchanger flows, through the gas suction pipeline 16 via the indoor finned heat exchanger gas return pipeline 14, into the two-stage compression oil-free centrifugal compressor 20 for compression, and then flows into the gas exhaust manifold 24 through the gas exhaust pipeline 21. Next, the refrigerant gas flows, through the outdoor finned heat exchanger gas inlet pipelines 25/29, 32/37, 39/44 and 46/51 respectively, into the outdoor finned heat exchangers 26/30, 33/36, 40/43, and 47/50. By adjusting the outdoor cooling heat exchanger fans 28, 38, 45 and 52, the refrigerant in the outdoor heat exchanger is cooled, and heat of the refrigerant is discharged into atmosphere. The cooled refrigerant is changed from gas to liquid, and flows, through the outdoor finned heat exchanger liquid outlet pipelines 27/31, 34/35, 41/42 and 48/49 respectively, into the refrigerant liquid main pipeline 1. Next, after being pressurized by the refrigerant circulating pump, the refrigerant is fed into the electronic expansion valve 3a, the electromagnetic valve 4 and the electronic expansion valve 3b for throttling respectively through the refrigerant circulating pump liquid outlet pipeline 5. The throttled refrigerant flows, through the refrigerant throttling distribution pipelines 6, 7, 8, 9, 10, 11 and 12 again, into the indoor finned heat exchanger 13 for evaporation, and then the evaporated refrigerant flows through the gas return pipeline again. In this way, a complete refrigeration cycle is formed.

According to the indoor load of the data room, the outdoor heat exchanger fans 28, 38, 45 and 51 and the indoor cooling heat exchanger fans 17a, 17b, 17c and 17d are adjusted respectively, and the indoor humidifier 18 is started, to obtain stable target temperature and humidity on an indoor side, thereby reducing power consumption of the outdoor and indoor heat exchanger fans. The two-stage compression oil-free centrifugal compressor carries out full-variable-speed control according to load requirements of the data room, which can save energy consumption.

The air conditioning unit for the data room according to the above method in the present disclosure can ensure air temperature and humidity and quality requirements of the data center room, meet accurate control of the air temperature in the data room, and maximize the use of natural energy, thereby saving energy. Furthermore, there is no need for consumption of water resources.

The plurality of outdoor cooling heat exchanger fans 28, 38, 45 and 52, the two-stage compression oil-free centrifugal compressors 20, and the refrigerant circulating pump 2 are under full-variable-speed control, and variable-frequency speed regulation operation is implemented according to their respective modes and load requirements of the data room, to achieve accurate control and improve energy efficiency. Operation modes of devices are automatically switched on a basis of hot air parameters from the data room and outdoor environmental parameters in combination with a pre-set control logic. The hot air parameters include temperature and humidity. The environmental parameters include temperature and humidity. The control logic is preset based on air supply parameters of the data room, such as a temperature range and a humidity range.

By adopting the above embodiments, the air temperature and humidity and quality requirements of the data room are generally met, problems of higher heat dissipation power and lower adjustment accuracy are solved for the servers in the data room, and operation reliability and safety of the devices in the data room are improved. Furthermore, natural energy is maximized, and energy consumption is saved due to precise adjustment of the two-stage compression oil-free centrifugal compressor and the refrigerant circulating pump subjected to full-variable-speed control. Furthermore, there is no need for consumption of water resources.

The foregoing descriptions are merely preferred embodiments of the present disclosure, and are not intended to limit the present disclosure. Any modification, equivalent replacement and improvement made within the spirit and principle of the present disclosure shall fall into the protection scope of the present disclosure.

What is claimed is:

1. An air conditioning unit for a data room, comprising: a plurality of outdoor finned heat exchangers, a plurality of corresponding outdoor cooling heat exchanger fans, a plurality of indoor cooling heat exchanger fans, an indoor finned heat exchanger, an indoor humidifier, a two-stage compression oil-free centrifugal compressor, a refrigerant circulating pump, an electronic expansion valve, an electromagnetic valve, an indoor air supply duct, and a refrigerant circulation connection pipeline; wherein
the plurality of outdoor finned heat exchangers are arranged in one-to-one correspondence with the plurality of corresponding outdoor cooling heat exchanger fans; a given one of the plurality of indoor cooling heat exchanger fans is configured to drive return air from the data room to enter the indoor air supply duct after the return air is subjected to heat exchange through the given indoor finned heat exchanger; the two-stage compression oil-free centrifugal compressor, the refrigerant circulating pump, the electronic expansion valve, and the electromagnetic valve are configured to regulate a refrigerant entering the given indoor finned heat exchanger, such that a cycle of heat exchange between the refrigerant and the plurality of outdoor finned heat exchangers is completed; and the indoor humidifier is configured to humidify air entering the indoor air supply duct.

2. The air conditioning unit for the data room according to claim 1 further comprising a check valve, wherein the check valve is arranged between the indoor finned heat exchanger and the two-stage compression oil-free centrifugal compressor to achieve a one-way flow of a condensate liquid to the two-stage compression oil-free centrifugal compressor.

3. The air conditioning unit for the data room according to claim 1, wherein the refrigerant circulation connection pipeline comprises: a pipeline connecting between the indoor finned heat exchanger and the two-stage compression oil-free centrifugal compressor; a pipeline connecting between the two-stage compression oil-free centrifugal compressor and the plurality of outdoor finned heat exchangers; a refrigerant liquid main pipeline connecting between the plurality of outdoor finned heat exchangers and the refrigerant circulating pump; a pipeline connecting between the refrigerant circulating pump and the electronic expansion valve and the electromagnetic valve; and a pipeline connecting between the electronic expansion valve, the electromagnetic valve, and the indoor finned heat exchanger.

4. The air conditioning unit for the data room according to claim 1, wherein the refrigerant circulating pump is a full-variable-speed refrigerant circulating pump configured to carry out variable-speed pressurization on a refrigerant liquid condensed by the plurality of outdoor finned heat exchangers.

5. The air conditioning unit for the data room according to claim 1, wherein the two electronic expansion valves are adjustable in opening degree, and on-off of the electromagnetic valve is controllable to regulate a flow rate of the refrigerant entering the indoor finned heat exchanger.

6. A control method for the air conditioning unit for a data room, wherein the air conditioning unit comprises a plurality of outdoor finned heat exchangers, a plurality of corresponding outdoor cooling heat exchanger fans, a plurality of indoor cooling heat exchanger fans, an indoor finned heat exchanger, an indoor humidifier, a two-stage compression oil-free centrifugal compressor, a refrigerant circulating pump, an electronic expansion valve, an electromagnetic valve, an indoor air supply duct, and a refrigerant circulation connection pipeline; the control method comprising:
in a first mode, regulating air volume of the plurality of outdoor cooling heat exchanger fans, cooling a refrigerant gas flowing through the outdoor finned heat exchanger by means of an outdoor natural cold source to transfer heat to outside air, such that the refrigerant is liquified; adjusting rotational speed of the refrigerant circulating pump to pressurize the liquefied refrigerant; adjusting an opening degree of the electronic expansion valve and turning on the electromagnetic valve, such that the liquefied refrigerant enters the indoor finned heat exchanger after reaching a required low pressure, to exchange heat with hot air from the data room; and regulating air volume of the indoor cooling heat exchanger fan and spray volume of the indoor humidifier to feed treated air into the data room;
in a second mode, further reducing the air volume of the plurality of outdoor cooling heat exchanger fans and reducing number of the outdoor finned heat exchangers, other steps being the same as the first mode;
in a third mode, further reducing the air volume of the plurality of outdoor cooling heat exchanger fans and reducing the number of the outdoor finned heat exchangers, other steps being the same as the first mode;
in a fourth mode, turning off all the plurality of outdoor cooling heat exchanger fans, turning off all the plurality of outdoor finned heat exchangers, regulating the air volume of the indoor cooling heat exchanger fan and the spray volume of the indoor humidifier to feed the treated air into the data room;
in a fifth mode, starting the two-stage compression oil-free centrifugal compressor, turning on all the plurality of outdoor cooling heat exchanger fans, and heating the refrigerant by means of mechanical compression, other steps being the same as the first mode;
in a sixth mode, adjusting the opening degree of the electronic expansion valve and turning off the electromagnetic valve, such that amount of the refrigerant entering the indoor finned heat exchanger is reduced, other steps being the same as the first mode; and
in a seventh mode, regulating the spray amount of the indoor humidifier and increasing moisture content in the air, other steps being the same as the first mode.

7. The control method according to claim 6, wherein the first mode is suitable for a case where outdoor temperature is lower and heat load of the data room is greater; the second mode is suitable for a case where the outdoor temperature and the heat load of the data room are further reduced; the third mode is suitable for a case where the outdoor temperature and the heat load of the data room are still further reduced; the fourth mode is suitable for a case where the outdoor temperature is extremely low and the heat load of the data room is smaller; the fifth mode is suitable for a case where the outdoor temperature rises and the heat load of the data room is greater; the sixth mode is suitable for a case where the data room has higher dehumidification demands; and the seventh mode is suitable for a case where the data room needs to increase dehumidification capacity.

8. The control method according to claim 6, wherein the plurality of outdoor cooling heat exchanger fans, the two-stage compression oil-free centrifugal compressor, and the refrigerant circulating pump are under full-variable-speed control, and variable-frequency speed regulation operation is implemented according to their respective modes and load requirements of the data room, to achieve accurate control and improve energy efficiency.

9. The control method according to claim 6, wherein operation modes of devices are automatically switched on a basis of hot air parameters from the data room and outdoor environmental parameters in combination with a pre-set control logic.

10. The control method according to claim 9, wherein the hot air parameters comprise temperature and humidity; the environmental parameters comprise temperature and humidity; and the control logic is set in advance according to requirements for air supply parameters of the data room, such as a temperature range and a humidity range.
